(19) United States
(12) Patent Application Publication
(10) Pub. No.: US 2012/0287606 A1
(43) Pub. Date: Nov. 15, 2012

(54) LED LIGHT SOURCE ASSEMBLY, BACK LIGHT MODULE AND LIQUID CRYSTAL DISPLAY DEVICE

(75) Inventors: Yonggang Xiao, Shenzhen (CN); Po-Iem Lin, Shenzhen (CN)

(73) Assignee: Shenzhen China Star Optoelectronics Technology Co., Ltd, Shenzhen, Guangdong (CN)

(21) Appl. No.: 13/376,841

(22) PCT Filed: May 19, 2011
(86) PCT No.: PCT/CN2011/074354

§ 371 Date: Dec. 8, 2011

(30) Foreign Application Priority Data
May 9, 2011 (CN) 201110118564.1

(51) Int. Cl. H01L 33/64; G09F 13/04

(52) U.S. Cl. 362/97.1; 257/99; 257/E33.075

(57) ABSTRACT

The present disclosure provides an LED light source assembly which includes an LED chip and a printed circuit board. The LED chip is arranged on the printed circuit board. At least a hole penetrating the printed circuit board is defined in the printed circuit board where the LED chip is arranged. A diameter of a first end of the hole adjacent to the LED chip is smaller than that of a second end of the hole far from the LED chip. An inner wall of the hole is coated with a heat conductive layer. The present disclosure also provides a backlight module and a liquid crystal display device with the LED light source assembly. The LED light source assembly, the backlight module and the liquid crystal display device provided in the present disclosure can improve the heat dissipation efficiency and extend the product life effectively.

### BACKGROUND

1. Technical Field

This present disclosure relates to LED light source assemblies, and in particular to an LED light source assembly used in the back light module of the LCD device.

2. Description of Related Art

LEDS (Light Emitting Diode) are widely used in such technical fields as lighting and LCD technical fields due to the advantages of low power consumption and long service life.

The existing LED light source assembly usually includes an LED chip and a PCB (Printed Circuit Board). The LED chip is arranged on a surface of the PCB to work as the light source. During working, the LED generates a large amount of heat. The LED with high power especially generates more heat. If there is no a structural with good heat dissipation effect, the service life of the LED and the reliability of the whole product will be seriously affected. Accordingly, a thermal conducting structure is generally arranged on the PCB to dissipate the heat. However, the conventional thermal conducting structure only includes a single heat dissipating way and conducts the heat in a one-dimensional way, making the heat cannot be dissipated timely and further resulting in the gathering of a large amount of heat, which affects the service life of the LED and the reliability of the whole product.

### SUMMARY

The main purpose of this present disclosure is to provide an LED light source assembly and a back light module and LCD Device based on the LED light source assembly to provide the heat dissipation efficiency.

In order to realize the purpose, this present disclosure provides an LED light source assembly. The LED light source assembly includes a PCB and an LED chip arranged on the PCB. At least a hole penetrating the PCB is defined in the PCB where the LED chip is arranged. The diameter of a first end of the hole adjacent to the LED chip is smaller than that of a second end of the hole far from the LED chip. An inner wall of the hole is coated with a heat conductive layer.

Preferably, an auxiliary heat dissipative layer is arranged on a surface of the PCB opposite to the surface arranged the LED chip. The auxiliary heat dissipative layer touches the heat conductive layer.

Preferably, an insulating solder layer is arranged between the LED chip and the PCB. The hole of the PCB penetrates the insulating solder layer. A heat dissipative coat with high thermal conductivity is arranged between the insulating solder layer and the LED chip.

Preferably, the heat dissipative coat contacts the heat conductive layer.

Preferably, an included angle is formed between the heat conductive layer and the axis of the hole and the included angle ranges from 20° to 30°.

Preferably, the included angle is 25°.

Preferably, the hole is filled with a heat conductor. The heat conductor s the heat conductive layer and the LED chip.

Preferably, the section of the hole is an isosceles trapezoid. The first end of the hole is the top base of the trapezoid and the second end opposite to the first end and is the bottom base of the trapezoid. The length of the bottom base is grater than the length of the top base.

The present disclosure also provides a back light module which includes an LED light source assembly. The LED light source assembly includes a PCB and an LED chip arranged on the PCB. At least a hole penetrating the PCB is defined in the PCB where the LED chip is arranged. The diameter of a first end of the hole adjacent to the LED chip is smaller than that of a second end of the hole far from the LED chip. The inner wall of the hole is coated with a heat conductive layer.

The present disclosure further provides an LCD device which includes an LCD panel and a back light module. The back light module includes an LED light source assembly. The LED light source assembly includes the PCB and the LED chip. The LED chip is arranged on the PCB. At least the hole penetrating the PCB is defined in the PCB where the LED chip is arranged. The diameter of a first end of the hole adjacent to the LED chip is smaller than that of a second end of the hole far from the LED chip. An inner wall of the hole is coated with a heat conductive layer.

### DESCRIPTION OF ATTACHED DRAWINGS

FIG. 1 is the structure view of a first embodiment of an LED light source assembly provided in this invention.

FIG. 2 is the structure view of a second embodiment of the LED light source assembly provided in this invention.

### DETAILED DESCRIPTION OF THE EMBODIMENTS

Hereinafter, a detailed description on the technical solutions to realize the object of the invention will be made when taken in conjunction with the attached drawings and the embodiments. It is understandable that the embodiments described here are only used to explain this invention instead of limiting this invention.

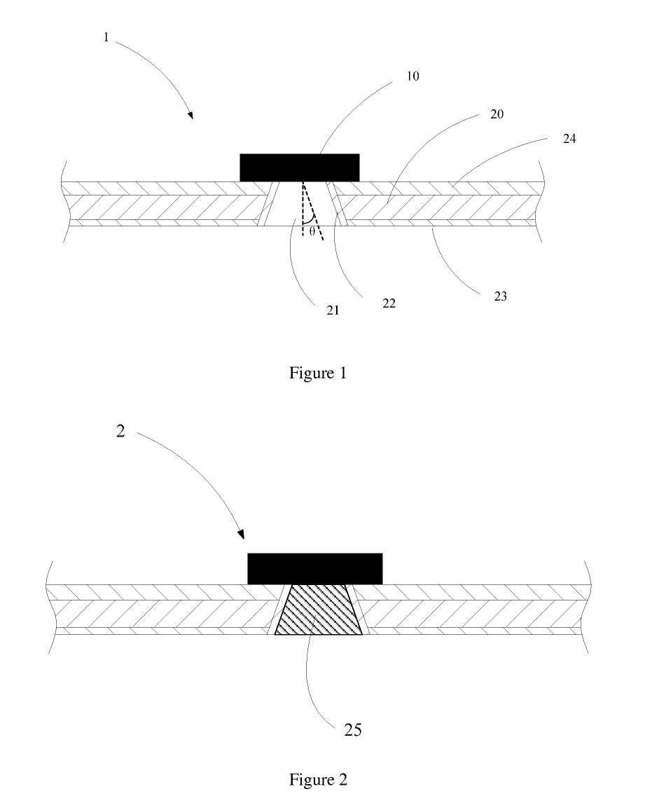

Referring to FIG. 1, an LED light source assembly 1 includes an LED chip 10 and a PCB 20. The LED chip 10 is arranged on the PCB 20. At least one hole 21 penetrating the PCB 20 is defined in the PCB 20 where the LED chip 10 is arranged. The hole 21 includes a first end adjacent to the LED chip 10 and a second end far from the LED chip 10. A diameter of the first end is smaller than that of a second end. The hole 21 further includes an inner wall coated with a heat conductive layer 22, and the heat conductive layer 22 can be made of materials such as copper, silver, or thermal grease, etc. The heat conductive layer 22 can be arranged on the inner wall of the hole 21 through the process of plated through hole, which is well-known in the field, and will not be described in detail.

Compared with the conventional structure, at least one hole 21 is defined in the PCB 20 where the LED chip 10 is arranged, the diameter of the end adjacent to the LED chip 10 of the hole 21 is smaller than that of the end far from the LED chip 10 of the hole 21, and the inner wall of the hole 21 is coated with the heat conductive layer 22, therefore, two heat dissipative ways thereof extend along the cross section and the longitudinal section of the hole 21 respectively are defined. Therefore, the LED light source assembly 1 is capable of dissipating the heat in a two two-dimensional way. What shall be stated is that the cross section and the longitudinal section referred to in the present disclosure are both relatively defined. In the embodiment, the cross section refers to the section perpendicular to the axis of the hole and the longitudinal section refers to the section parallel to the axis of the hole. The two-dimensional heat dissipative way is different from the traditional one-dimensional heat dissipative way which extends mainly along one direction of the cross section and the longitudinal section, which has relatively bad heat dissipation effect.

In an embodiment, an auxiliary heat dissipative layer 23 is arranged on a surface of the PCB 20 opposite to the surface disposed with the LED chip 10 and connects to the heat conductive layer 22. The auxiliary heat dissipative layer 23 spreads the heat transferring from the heat conductive layer 22 to reduce the heat gathering surrounding the LED chip 10 so as to further improve the heat dissipation efficiency. The auxiliary heat dissipative layer 23 is made of gold, silver, copper, or other materials with high thermal conductivity. The auxiliary heat dissipative layer 23 can be a plastic coat with high thermal conductivity arranged on the PCB 20 or a metal block with high thermal conductivity attached on the PCB 20.

Additionally, an insulating solder layer 24 is arranged between the LED chip 10 and the PCB 20. The hole 21 penetrates the solder layer 24. A heat dissipative coat with high thermal conductivity is arranged between the insulating solder layer 24 and the LED chip 10. The heat dissipative coat connects to the heat conductive layer 22 to transfer the heat generated by the LED chip 10 to the heat conductive layer 22. Therefore, the gathering of the heat generated by the LED chip 10 between the insulating solder layer 24 and the LED chip 10 can be avoided, and the damage of the LED chip 10 caused by the heat which can not be dissipated timely can be avoided, too. The heat dissipative coat can be made of silver, copper, and etc.

Besides, in the two-dimensional heat transfer way of the LED light source assembly of this disclosure, since the heat generated by the LED chip is dissipated along the two directions of the cross section and longitudinal section of the hole 21, therefore, the heat dissipation area of the LED chip 10 is shaped as a trumpet. Accordingly, the heat conductive layer 22 arranged on the inner wall of the hole 21 can be shaped as a trumpet. In this state, there is a corresponding relationship between an included angle formed by the heat conductive layer 22 and the axis of the hole 21 and a flare angle of the trumpet shape formed in the heat dissipation area, which can improve the heat dissipation effect of the LED chip 10. As shown in FIG. 1, assume the included angle between the heat conductive layer 22 and the axis of the hole 21 is θ, the flare angle of the trumpet shape formed in the heat dissipation area is twice the included angle θ. Generally, the flare angle of the trumpet shape formed in the heat dissipation area ranges from 40° to 60°, thus the included angle θ ranges from 20° to 30°. When the flare angle of the trumpet shape is 50°, the heat dissipation effect is relatively better, and the θ shall be 25° according to the relationship between the included angle and the flare angle 2θ=50°. There are several options on the included angle θ such as 20° or 30°.

Further, the section shape of the hole 21 of the LED light source assembly 1 in the embodiment can also be an isosceles trapezoid, with the first end thereof as a top base of the isosceles trapezoid and the second end thereof as a bottom base of the isosceles trapezoid. A length of the bottom base is greater than that of the top base.

A number of the LED chips 10 can be arranged on the same PCB as required. The hole 21 can be correspondingly arranged with the LED chip 10 one-by-one, which can be processed and shaped through NC drill, punching, or laser drill. The cross section of the hole 21 can be rounded or polygonal such as a conoid hole or a prism frustum hole.

FIG. 2 is a schematic view of the LED light source assembly according to a second embodiment of the present disclosure. The differences between the LED light source assembly 2 of this embodiment and the light source assembly 1 of the first embodiment lie in: the hole 21 is filled up with a heat conductor 25. The heat conductor 25 contacts the heat conductive layer and the LED chip 10. The heat conductor 25 can be made of metal materials such as aluminum, copper, iron, etc. or made of the same material as that of the heat conductive layer. Also, the heat conductor can be integral with the heat conductive layer.

Since the LED light source assembly 2 is provided with the heat conductor 25, and the heat transferring efficiency of the heat conductor 25 is better than that of the air, thus, the heat generated by the LED chip 10 is spread through the heat conductor 25 and diffuses fast, improving the heat dissipation efficiency of the LED chip 10.

In an embodiment, the heat conductor 25 is poured into the hole 21 to fill in the hole 21. Thus, the heat conductor 25 can contact the LED chip 10 directly, increasing the contacting area therebetween and enabling the fast conduction of the heat.

In the above embodiment, the material of the heat conductive layer 22 and the material of the heat conductor 25 can be different. In some situations where the printed circuit board is relatively thinker, the heat conductor 25 can be shaped corresponding to the shape and size of the hole 21 and is connected to the hole 21 by crimping or other mechanical connection ways.

The LED light source assembly 1 or the LED light source assembly 2 provided in the present disclosure can be used in a variety of fields which need to dissipate heat generated by the printed circuit board and the LEDs assembly in backlight modules of LCD devices or lamp. For example, the LED light source assembly 1 or the light source assembly 2 is applied in a LCD device, the LCD device includes a LCD panel and a backlight module, wherein, the backlight module includes the LED light source assembly 1 or the LED light source assembly 2 provided in the embodiment.

The present disclosure further provides a backlight module with the LED light source assembly 1 in the first embodiment or the LED light source assembly 2 in the second embodiment. The backlight module can be used in liquid crystal displays such as liquid crystal televisions and displays of personal computers. With the LED light source assembly 1 or the LED light source assembly 2, the backlight module can dissipate the heat quickly and lengthen the life of a product with the backlight module.

The present disclosure further provides a liquid crystal display with the liquid crystal panel and the backlight module, the backlight module can be used in liquid crystal displays such as liquid crystal televisions and displays of personal computers. The backlight module includes a LED light source assembly. The LED light source assembly can be the LED light source assembly 1 of the first embodiment or the LED light source assembly 2 of the second embodiment. In a preferable embodiment, the LED light source assembly is the LED light source assembly 1 of the first embodiment. As what is described above, the LED light source assembly 1 includes the PCB 20 and the LED chip 10 arranged on the PCB 20. The hole 21 penetrating the PCB is defined in the PCB 20 where the LED chip 10 is arranged. The hole 21 includes the first end adjacent to the LED chip 10 and the second end far from the LED chip 10. A diameter of the first end is smaller than that of the second end. The hole 21 further includes the inner wall coated with the heat conductive layer 22. The included angle arranging from 20° to 30° is formed between the heat conductive layer 25 and an axe of the hole 21. Preferably, the included angle is 25°.

In another preferable embodiment, the LED light source assembly of the liquid crystal display is the LED light source assembly 2 of the second embodiment. As what is described above, the hole 21 of the LED light source assembly 2 is filled up with the heat conductor 25. The heat conductor 25 contacts the heat conductive layer 22 and the LED chip 10, or is integral with the heat conductive layer 22. With the heat conductor 25 which has higher heat conductivity, the heat generated from the LED chip 10 can be dissipated quickly, which improves the heat dissipating efficiency of the LED chip 10. It is noted that the heat conductor 25 can be made of silver, copper, and etc., or material as the same that of the heat conductive layer 22.

As is well known, in an LCD device, the LED light source assembly is the key lighting assembly, and its service life directly influences the life of the LCD device. In the embodiments provided in the present disclosure, since the LED light source assembly 1 or the LED light source assembly 2 is provided in the backlight module, the LCD device in the present disclosure has a better heat dispersion performance and a longer service life compared with the conventional LCD device.

The LED light source assembly is not limited to the embodiments. In other embodiments, the heat conductor 25 can be designed into various shapes such as the round platform shape or the prism frustum shape according to the trumpet-shaped flare angle of the heat dissipation path of the LED light source assembly. Also, the heat conductor 25 can be made of plastic material with high thermal conductivity etc. Equivalent structures or equivalent transformation processes made with contents of descriptions and figures of this invention, or applying contents of descriptions and figures of this invention in other relevant fields all included in the scope of patent protection of this invention for the same reason.

What is claimed is:

1. An LED light source assembly comprising:
a printed circuit board;
an LED chip arranged on the printed circuit board;
wherein at least one hole penetrating the printed circuit board is defined in the printed circuit board where the LED chip is arranged, a diameter of a first end of the hole adjacent to the LED chip is smaller than that of a second end of the hole far from the LED chip, and an inner wall of the hole is coated with a heat conductive layer.

2. The LED light source assembly as claimed in claim 1, wherein an auxiliary heat dissipating layer is arranged on a surface of the printed circuit board opposite to the surface arranged the LED chip, and the auxiliary heat dissipating layer contacts the heat conductive layer.

3. The LED light source assembly as claimed in claim 1, wherein an insulating solder layer is arranged between the LED chip and the printed circuit board, the hole of the printed circuit board penetrates the insulating solder layer, and a heat dissipative coat with high thermal conductivity is arranged between the insulating solder layer and the LED chip.

4. The LED light source assembly as claimed in claim 3, wherein the heat dissipating coating contacts the heat conductive layer.

5. The LED light source assembly as claimed in claim 1, wherein an included angle is formed between the heat conductive layer and the axis of the hole, and the included angle arranges from 20° to 30°.

6. The LED light source assembly as claimed in claim 5, wherein the included angle is 25°.

7. The LED light source assembly as claimed in claim 1, wherein the hole is filled with a heat conductor and the heat conductor contacts the heat conductive layer and the LED chip.

8. The LED light source assembly as claimed in claim 1, wherein the section shape of the hole is an isosceles trapezoid, the first end of the hole is the top base of the trapezoid, the second end is opposite to the first end and is the bottom base of the trapezoid, and the length of the bottom base is longer than that of the top base.

9. A backlight module comprising an LED light source assembly, the LED light source assembly comprising:
a printed circuit board;
an LED chip arranged on the printed circuit board;
wherein at least a hole penetrating the printed circuit board is defined in the printed circuit board where the LED chip is arranged, the diameter of a first end of the hole adjacent to the LED chip is smaller than that of a second end of the hole far from the LED chip, and an inner wall of the hole is coated with a heat conductive layer.

10. The back light module as claimed in claim 9, wherein an auxiliary heat dissipating layer is arranged on a surface of the printed circuit board opposite to the surface arranged the LED chip, and the auxiliary heat dissipating layer contacts the heat conductive layer.

11. The back light module as claimed in claim 9, wherein an insulating solder layer is arranged between the LED chip and the printed circuit board, the hole of the printed circuit board penetrates the insulating solder layer, and a heat dissipative coat with high thermal conductivity is arranged between the insulating solder layer and the LED chip.

12. The back light module as claimed in claim 11, wherein the heat dissipating coating contacts the heat conductive layer.

13. The back light module as claimed in claim 9, wherein an included angle is formed between the heat conductive layer and the axis of the hole, and the included angle arranges from 20° to 30°.

14. The back light module as claimed in claim 13, wherein the included angle is 25°.

15. The back light module as claimed in claim 9, wherein the hole is filled with a heat conductor and the heat conductor contacts the heat conductive layer and the LED chip.

16. The back light module as claimed in claim 9, wherein the section shape of the hole is an isosceles trapezoid, the first end of the hole is the top base of the trapezoid, the second end of the hole is opposite to the first end and is the bottom base of the trapezoid, and the length of the bottom base is grater than the length of top base.

17. A liquid crystal display device, comprising:
a liquid crystal display panel;
a backlight module comprising an LED light source assembly, the LED light source assembly comprising:
a printed circuit board;
an LED chip arranged on the printed circuit board;
wherein at least a hole penetrating the printed circuit board is defined in the printed circuit board where the LED chip is arranged, the diameter of a first end of the hole adjacent to the LED chip is smaller than that of a second end of the hole far from the LED chip, and an inner wall of the hole is coated with a heat conductive layer.

18. The liquid crystal display device as claimed in claim 17, wherein the hole is filled with a heat conductor, the heat conductor contacts the heat conductive layer and the LED chip.

19. The liquid crystal display device as claimed in claim 17, wherein an included angle is formed between the heat conductive layer and the axis of the hole, and the included angle arranges from 20° to 30°.

20. The liquid crystal display device as claimed in claim 17, wherein an insulating solder layer is arranged between the LED chip and the printed circuit board, the hole of the printed circuit board penetrates the insulating solder layer, and a heat dissipative coat with high thermal conductivity is arranged between the insulating solder layer and the LED chip, and the dissipating coating contacts the heat conductive layer.
